(19) United States
(12) Patent Application Publication
(10) Pub. No.: US 2015/0249113 A1
(43) Pub. Date: Sep. 3, 2015

(54) NONVOLATILE MEMORY DEVICE

(71) Applicant: Kabushiki Kaisha Toshiba, Minato-ku (JP)

(72) Inventors: Takeshi TAKAGI, Yokkaichi-shi (JP); Shigeki Kobayashi, Kuwana-shi (JP); Takeshi Yamaguchi, Yokkaichi-shi (JP)

(73) Assignee: Kabushiki Kaisha Toshiba, Minato-ku (JP)

(21) Appl. No.: 14/293,432

(22) Filed: Jun. 2, 2014

Related U.S. Application Data
(60) Provisional application No. 61/946,429, filed on Feb. 28, 2014.

(51) Int. Cl. H01L 27/24; H01L 45/00

(52) U.S. Cl. CPC H01L 27/2463; H01L 45/1233; H01L 27/2436

(57) ABSTRACT

According to one embodiment, a nonvolatile memory device includes a first wiring, a second wiring, and a memory cell that is disposed at a position where the first and second wirings cross so as to be interposed between the first and second wirings. The memory cell includes a variable resistive layer and a tunnel barrier layer that is formed of an insulating film provided in contact with the variable resistive layer. The tunnel barrier layer is provided close to the first wiring to which a positive voltage with applied during set operation changing the variable resistive layer to a low-resistance state from a high-resistance state.

### CROSS-REFERENCE TO RELATED APPLICATIONS

This application is based upon and claims the benefit of priority from U.S. Provisional Application No. 61/946,429, filed on Feb. 28, 2014; the entire contents of which are incorporated herein by reference.

### FIELD

Embodiments described herein relate generally to a nonvolatile memory device.

### BACKGROUND

A resistive random access memory (hereinafter, referred to as ReRAM) in which a variable resistive layer capable of retaining a plurality of resistance states is used in a memory element is known. A memory cell of ReRAM that has a two-layer structure in which a first variable resistive layer and a second variable resistive layer of which the resistance is lower than the resistance of the first variable resistive layer are stacked between a first electrode and a second electrode has been proposed in the related art. In this memory cell, the second variable resistive layer functions as a load resistive element through the increase of the bulk resistance of the second variable resistive layer, and a small filament is formed in the first variable resistive layer by forming operation in which a voltage is applied to the first electrode contacting with the first variable resistive layer. The compatibility between low current drive and data retention characteristics is achieved in the memory cell that is formed in this way.

However, it is necessary to increase the thickness of the second variable resistive layer in order to make the second variable resistive layer function as a load resistive element in the memory cell in the related art. For this reason, it was difficult to reduce the size of the memory cell.

### BRIEF DESCRIPTION OF THE DRAWINGS

FIG. 1 is a cross-sectional view schematically illustrating an example of the structure of a nonvolatile memory device according to a first embodiment;

FIGS. 2A to 2C are diagrams schematically illustrating examples of a resistance state and the state of a filament;

FIG. 3 is a diagram illustrating an example of voltage-current characteristics of a variable resistive element;

FIG. 4 is a cross-sectional view schematically illustrating an example of the structure of a nonvolatile memory device according to a second embodiment;

FIG. 5 is a diagram illustrating an example of a block diagram of a nonvolatile memory device according to a first application example;

FIG. 6 is a bird's-eye view illustrating an example of the structure of a memory cell array of FIG. 1;

FIG. 7 is a perspective view illustrating an example of the structure of lines and cell units of a cross-point type memory cell array;

FIGS. 8A and 8B are diagrams illustrating a first example of a layout of first and second control circuits;

FIG. 9 is a diagram illustrating a second example of the layout of the first and second control circuits;

FIG. 10 is a diagram schematically illustrating an example of voltage-current characteristics of a tunnel barrier layer;

FIG. 11 is a diagram illustrating an example of a block section of a nonvolatile memory device according to a second application example;

FIG. 12 is a diagram illustrating an example of a circuit diagram of a memory cell array;

FIG. 13 is a perspective view illustrating an example of the stacked structure of the memory cell array;

FIG. 14 is an example of a cross-sectional view taken along line A-A of FIG. 13; and

FIG. 15 is an example of a top view of FIG. 13.

### DETAILED DESCRIPTION

According to an embodiment, there is provided a nonvolatile memory device that includes a first wiring, a second wiring, and a memory cell. The first wiring extends in a first direction. The second wiring is formed at a height different from the height of the first wiring and extends in a second direction crossing the first direction. The memory cell is disposed at a position where the first and second wirings cross so as to be interposed between the first and second wirings. The memory cell includes a variable resistive layer of which a resistance state is able to be changed by an electrical signal to be applied, and a tunnel barrier layer that is formed of an insulating film provided in contact with the variable resistive layer. The tunnel barrier layer is provided close to the first wiring to which a positive voltage with applied during set operation changing the variable resistive layer to a low-resistance state from a high-resistance state.

Nonvolatile memory devices according to embodiments will be described in detail below with reference to the accompanying drawings. Meanwhile, the invention is not limited by these embodiments. Further, a cross-sectional view, a top view, and a perspective view of the nonvolatile memory device used in the following embodiments are schematic diagrams. A relationship between the thickness and the width of the layer, a ratio of the thickness of each layer, and the like may be different from an actual relationship between the thickness and the width of the layer, an actual ratio of the thickness of each layer, and the like.

### First Embodiment

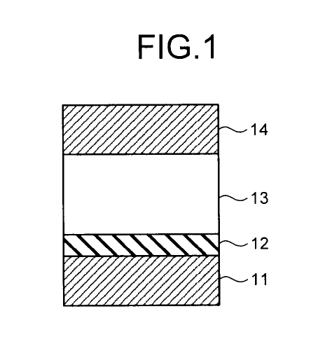

FIG. 1 is a cross-sectional view schematically illustrating an example of the structure of a nonvolatile memory device according to a first embodiment. A variable resistive element as one memory cell (nonvolatile memory cell) forming the nonvolatile memory device is illustrated in FIG. 1. The variable resistive element has a structure in which a tunnel barrier layer 12, a variable resistive layer 13, and a second electrode 14 are stacked on a first electrode 11.

For example, conductive semiconductor materials, such as W, Ti, WN, TiN, and p-type or n-type polysilicon, can be used as materials of the first and second electrodes 11 and 14.

The variable resistive layer 13 can be made of a variable resistive material of which the resistance state can be switched to a high-resistance state and a low-resistance state according to the polarity (direction) of a voltage to be applied. For example, metal oxides including at least one element of Al, Ti, Hf, Zr, Nb, and Ta are used as this variable resistive material. It is preferable that these metal oxides be metal oxides of which oxygen composition is less than that of a metal oxide having a stoichiometric ratio.

When a negative voltage lower than a first threshold voltage is applied to the variable resistive layer 13, the resistance state of the variable resistive layer 13 is switched to a low-resistance state. When a positive voltage higher than a second threshold voltage is applied to the variable resistive layer 13 in this state, the resistance state of the variable resistive layer 13 is switched to a high-resistance state. Further, when a voltage between the first and second threshold voltages is applied, a low-resistance state or a high-resistance state is maintained without the change of a resistance value. As described above, the variable resistive layer 13 may be made of a material that performs a so-called bipolar type operation. Meanwhile, in the first embodiment, a filament is formed between the first and second electrodes 11 and 14 by forming operation and a switch area is formed near an interface between the filament and the second electrode 14. At this point, the switch area is resistance changing area in resistance changing operation (switch operation).

The tunnel barrier layer 12 is an insulating film that is provided on the side of the variable resistive layer 13 facing the first electrode 11. More exactly, the tunnel barrier layer 12 is provided in an area opposite to the switch area that is formed on the variable resistive layer 13. The tunnel barrier layer 12 has a high potential barrier and functions as a load resistive element. For this reason, the tunnel barrier layer 12 has a function of limiting current during the forming operation and the operation. As a result, a filament is formed between the first and second electrodes 11 and 14 of the variable resistive layer 13. In addition, the switch area is formed near an interface of the second electrode 14 that is provided on the side of the filament opposite to the tunnel barrier layer 12. When the filament becomes small (fine) as described above, it is possible to reduce current that is required for the opening/closing of a filament path causing the switching of a resistance state. Accordingly, it is possible to achieve low current drive.

For example, a metal oxide such as a silicon oxide and an aluminum oxide, a metal nitride such as a silicon nitride and an aluminum nitride, or the like can be used as the tunnel barrier layer 12. Further, in order to improve characteristics of the load resistive element, it is preferable that the thickness of the tunnel barrier layer 12 be 2 nm or less. Furthermore, it is preferable that the thickness of the tunnel barrier layer 12 be equal to or smaller than the thickness of the variable resistive layer 13.

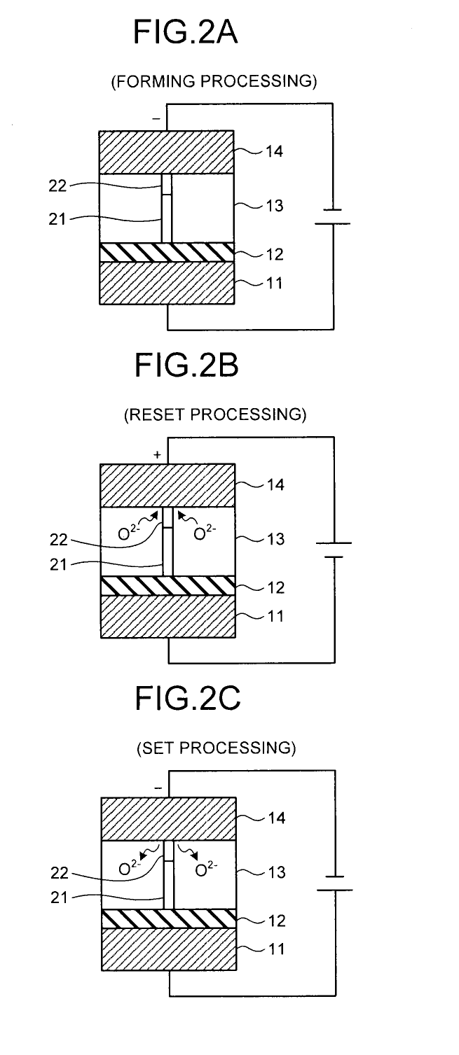

Next, the operation of the nonvolatile memory device having this structure will be described. FIGS. 2A to 2C are diagrams schematically illustrating examples of the resistance state and the state of the filament. The variable resistive layer 13 is in a state of an insulator immediately after the nonvolatile memory device illustrated in FIG. 1 is manufactured. For this reason, forming operation for forming a filament in the variable resistive layer 13 of the variable resistive element is performed. In this forming operation, a negative voltage (forming voltage) is applied to the second electrode 14 with respect to the first electrode 11 as illustrated in FIG. 2A. At this time, the tunnel barrier layer 12 serves as a load resistive element, so that current flowing in the variable resistive layer 13 is suppressed. Accordingly, a filament 21 is formed between the first and second electrodes 11 and 14, so that the variable resistive layer 13 is in a low-resistance state. Further, a switch area 22 of which the oxygen content is changed by an oxidation-reduction reaction of set operation or reset operation to be performed later is formed near the interface of the filament 21 facing the second electrode 14.

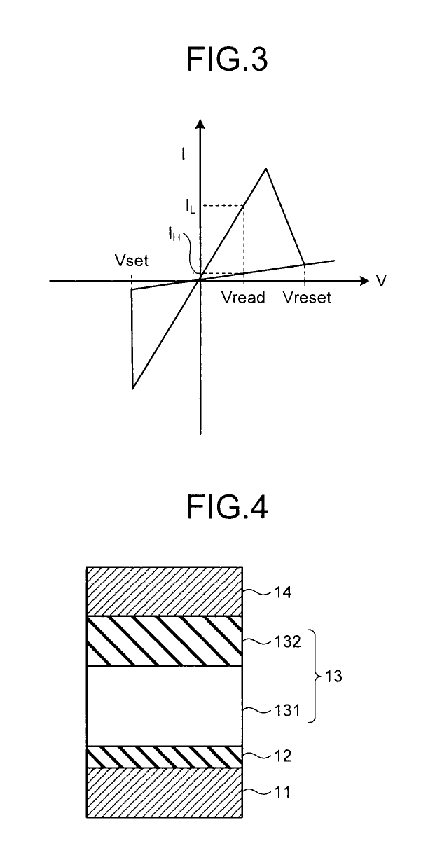

After the filament 21 is formed by this forming operation, the resistance state of the variable resistive layer 13 is switched to a high-resistance state and a low-resistance state by a voltage applied between the first and second electrodes 11 and 14. It is considered that an oxidation-reduction reaction occurs in the fine filament 21 (switch area 22) formed on the interface of the second electrode 14 and this switching occurs due to the change of the resistance value of the filament. FIG. 3 is a diagram illustrating an example of voltage-current characteristics of the variable resistive element. In FIG. 3, a horizontal axis represents a voltage applied to the variable resistive element and a vertical axis represents current flowing in the variable resistive element. A switch operation between the low-resistance state and the high-resistance state will be described with reference to FIGS. 2B, 2C, and 3.

In a switch operation (reset operation) to a high-resistance state from a low-resistance state, a positive voltage Vreset is applied to the second electrode 14 with reference to the first electrode 11. Accordingly, oxygen ions O²⁻ contained in the variable resistive layer 13 are attracted to the switch area 22, so that an oxidation reaction occurs in the switch area 22 of the filament 21. As a result, it is considered that the resistance state of the variable resistive layer 13 is switched to a high-resistance state due to the increase of the resistance of the switch area 22.

In contrast, in a switch operation (set operation) to a low-resistance state from a high-resistance state, a negative voltage Vset is applied to the second electrode 14 with reference to the first electrode 11. Accordingly, oxygen ions O²⁻ contained in the switch area 22 of the filament 21 are pushed toward the first electrode 11, so that a reduction reaction occurs in the switch area 22 of the filament 21. As a result, it is considered that the resistance state of the variable resistive layer 13 is switched to a low-resistance state due to the decrease of the resistance of the switch area 22.

Further, when a read-out voltage Vread is applied to the variable resistive element that has been subjected to the reset operation or the set operation, a value of current flowing in the variable resistive layer 13 in a high-resistance state is different from a value of current flowing in the variable resistive layer 13 in a low-resistance state. For example, when a current value in a high-resistance state (a state after the reset operation has been performed) is denoted by I_{H} and a current value in a low-resistance state (a state after the set operation has been performed) is denoted by I_{L}, it is possible to determine whether the variable resistive element is in a high-resistance state or a low-resistance state by detecting these current values I_{H} and I_{L}. As described above, the variable resistive element is made to be in a high-resistance state/low-resistance state by the reset operation and the set operation and stores information about a resistance value, and the variable resistive element is made to function as a memory by the detection of a difference in the current flowing in the variable resistive element.

In the first embodiment, the variable resistive element, which is provided with the variable resistive layer 13 between the first and second electrodes 11 and 14, is provided with the tunnel barrier layer 12 between the first electrode 11 and the variable resistive layer 13. Accordingly, during the forming operation, the filament 21 is formed in the variable resistive layer 13 and the switch area 22 in which a resistance change (switching operation) is mainly performed is formed in the filament 21 on the side opposite to the tunnel barrier layer 12 (the side of the filament 21 facing the second electrode 14). Further, at this time, it is possible to obtain an effect of suppressing current, which flows in the variable resistive element, by the tunnel barrier layer 12. Furthermore, since the switching of a resistance change is only used at the small filament 21, current flowing during the set operation or the reset operation can also be reduced and sufficient data retention characteristics can be obtained.

### Second Embodiment

A case in which the variable resistive layer 13 is formed of one layer has been described in the first embodiment, but a case, in which the variable resistive layer 13 is formed of two layers having different resistivities, will be described in a second embodiment.

FIG. 4 is a cross-sectional view schematically illustrating an example of the structure of a nonvolatile memory device according to a second embodiment. A variable resistive element as one memory cell forming the nonvolatile memory device is illustrated in FIG. 4. The variable resistive element is different from the first embodiment in that a variable resistive layer 13 includes a first variable resistive layer 131 and a second variable resistive layer 132.

The first variable resistive layer 131 is formed on a tunnel barrier layer 12, and is made of a metal oxide. For example, metal oxides including at least one element of Al, Ti, Hf, Zr, Nb, and Ta are used as the first variable resistive layer 131. The oxygen composition of these metal oxides is less as compared to a stoichiometric ratio of the metal oxide material.

The second variable resistive layer 132 is formed of an insulating film of which the resistivity is higher than the resistivity of the first variable resistive layer 131. For example, a metal oxide such as a silicon oxide and an aluminum oxide, a metal nitride such as a silicon nitride and an aluminum nitride, or the like is used as the second variable resistive layer 132.

In forming operation, a filament 21 is formed in the first and second variable resistive layers 131 and 132 and a switch area 22 in which a resistance change (switching operation) is performed is formed in the filament 21 on the side facing the second electrode 14. For this reason, in the second embodiment, the tunnel barrier layer 12 is provided on the side opposite to the position of the second variable resistive layer 132. Meanwhile, the same components as the components of the first embodiment are denoted by the same reference numerals, and the description thereof will be omitted.

It is preferable that the thickness of the tunnel barrier layer 12 be equal to or smaller than the thickness of the variable resistive layer 13 and be 2 nm or less. The reason for this is that an effect as a load resistor can be improved.

Further, a relationship between the thickness of the second variable resistive layer 132 and the thickness of the tunnel barrier layer 12 is not particularly limited. However, in order to apply preferentially a voltage to the second variable resistive layer 132 during the forming operation in which a positive voltage is applied to the second electrode 14 with respect to the first electrode 11, it is preferable that the thickness of the second variable resistive layer 132 be larger than the thickness of the tunnel barrier layer 12. This is the same meaning as that the band gap of the second variable resistive layer 132 is larger than the band gap of the tunnel barrier layer 12. According to this, it is possible to fix the position of an area, of which resistance is changed (switch area 22), to the second variable resistive layer 132.

Furthermore, when the tunnel barrier layer 12 functions as a resistive component or a voltage, which is applied to the variable resistive layer 13 during the set operation or the reset operation, is certain high value by the tunnel barrier layer 12 having non-linear voltage-current characteristics, it is preferable that the thickness of the tunnel barrier layer 12 be large. Providing a potential barrier such as the tunnel barrier layer 12 formed between the first variable resistive layer 131 and the first electrode 11 so that the variable resistive element has non-linear voltage-current characteristics. This is the same meaning as that the band gap of the tunnel barrier layer 12 is larger than the band gap of the first variable resistive layer 131.

Meanwhile, there is an optimum thickness of the second variable resistive layer 132 so as to change resistance by the second variable resistive layer 132 (to form the switch area 22 in the second variable resistive layer 132). The thickness of the tunnel barrier layer 12 is changed relative to the optimum thickness of the second variable resistive layer 132 based on the fixing of the position of the switch area 22 formed in the filament 21 or the non-linear voltage-current characteristics.

The operation of the nonvolatile memory device having this structure is also the same as that of the first embodiment. However, in the second embodiment, a potential difference is applied to the second variable resistive layer 132 during the forming operation due to the tunnel barrier layer 12, so that the switch area 22 is formed in the filament 21 of the second variable resistive layer 132.

The second embodiment has the same effect as the effect of the first embodiment. Further, in the second embodiment, the tunnel barrier layer 12, which does not contribute to a resistance change, is included in the variable resistive element in which the first variable resistive layer 131, the second variable resistive layer 132, and the second electrode 14 are stacked above the first electrode 11 in this order. Accordingly, a voltage is preferentially applied to the second variable resistive layer 132 during the forming operation, so that it is possible to obtain an effect of forming the switch area 22 in the second variable resistive layer 132.

### First Application Example

The memory cells of the first and second embodiments can be applied to a nonvolatile memory device using the following variable resistive elements.

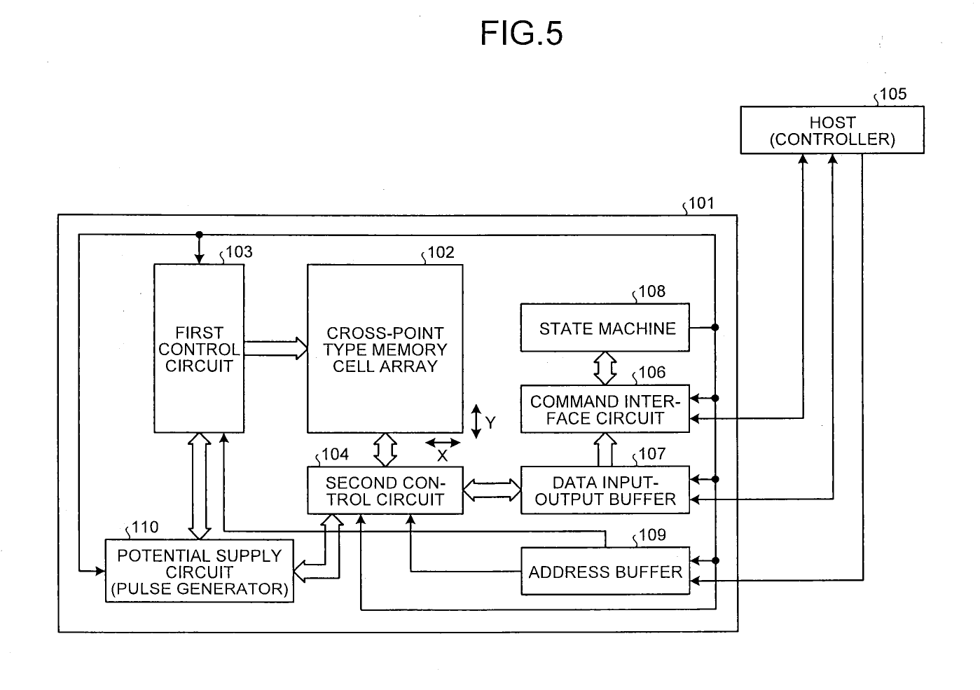

FIG. 5 is a diagram illustrating an example of a block diagram of a nonvolatile memory device according to a first application example. The nonvolatile memory device (for example, chip) 101 includes a cross-point type memory cell array 102. A first control circuit 103 is disposed at one end of the memory cell array 102 in an X direction, and a second control circuit 104 is disposed at one end of the memory cell array 102 in a second direction crossing the X direction.

The first control circuit 103 selects a row of the memory cell array 102 on the basis of, for example, a row address signal. Further, the second control circuit 104 selects a column of the memory cell array 102 on the basis of, for example, a column address signal. The first and second control circuits 103 and 104 control the writing of data in memory elements of the memory cell array 102 and the erasing and the reading of data from the memory elements of the memory cell array 102.

Here, for example, writing is called set and erasing is called reset in this nonvolatile memory device 101. A resistance value in a set state has only to be different from a resistance value in a reset state, and it is not important whether the resistance value in the set state is larger or smaller than the resistance value in the reset state. Furthermore, it is also possible to achieve a multi-level variable resistive memory, of which one memory element stores multi-level data, by selectively writing one level among levels of a plurality of resistance values, which are taken by the memory elements, in a set operation.

A controller 105 supplies a control signal and data to a variable resistive memory 101. The control signal is input to a command interface circuit 106, and the data are input to a data input-output buffer 107. The controller 105 may be disposed in the chip 101, and may be disposed in another chip (host device) different from the chip 101.

The command interface circuit 106 determines whether or not data supplied from the controller 105 are command data, on the basis of the control signal. If the data are command data, the data are transmitted to a state machine 108 from the data input-output buffer 107.

The state machine 108 manages the operation of the variable resistive memory 101 on the basis of the command data. For example, the state machine 108 manages a set/reset operation and a read operation on the basis of the command data supplied from the controller 105. The controller 105 receives status information managed by the state machine 108, and also can determine an operation result of the variable resistive memory 101.

In the set/reset operation and the read operation, the controller 105 supplies an address signal to the variable resistive memory 101. The address signal is input to the first and second control circuits 103 and 104 through an address buffer 109.

A potential supply circuit 110 outputs a voltage pulse or a current pulse, which is necessary for, for example, the set/reset operation and the read operation, at a predetermined timing on the basis of a command output from the state machine 108. The potential supply circuit 110 includes a pulse generator, and controls a voltage value/a current value and a pulse width of a voltage pulse/a current pulse, which is to be output, according to an operation that is represented by the command data and the control signal.

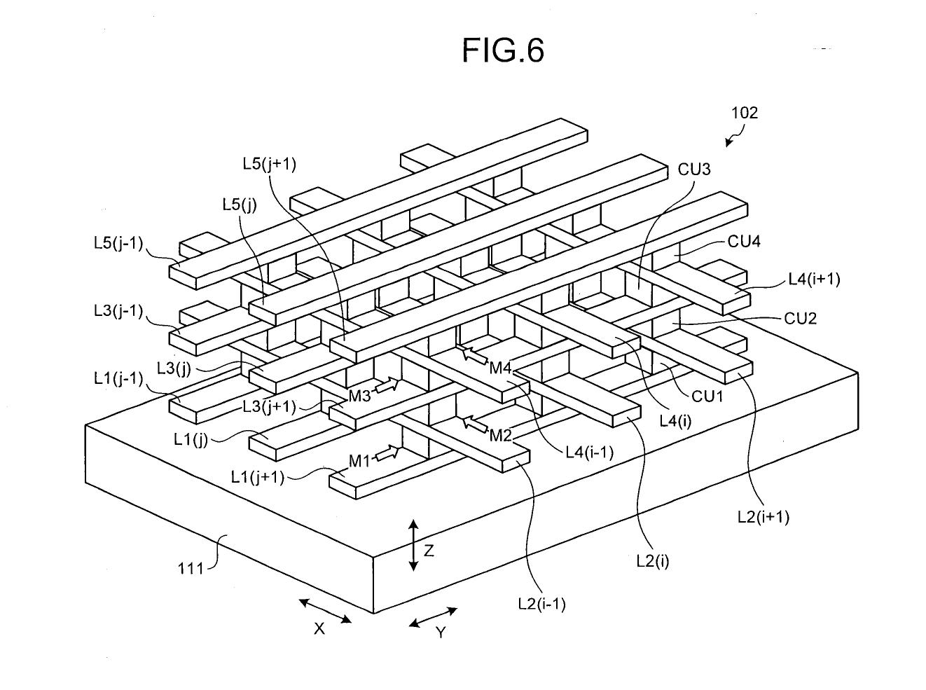

FIG. 6 is a bird's-eye view illustrating an example of the structure of the memory cell array of FIG. 1. The memory cell array illustrated in FIG. 2 has a cross-point type structure. The cross-point type memory cell array 102 is disposed above a substrate 111. The substrate 111 is a semiconductor substrate (for example, a silicon substrate), or an interlayer insulating film provided on the semiconductor substrate. Meanwhile, when the substrate 111 is the interlayer insulating film, a circuit using a field effect transistor or the like may be formed on the surface of the semiconductor substrate, which is disposed under the cross-point type memory cell array 102, as a peripheral circuit of a memory.

For example, the cross-point type memory cell array 102 is formed by the stacked structure of a plurality of memory cell arrays (which are also called memory cell layers). FIG. 6 illustrates a case in which the cross-point type memory cell array 102 may be formed of four memory cell arrays M1, M2, M3, and M4 stacked in a Z direction (a direction perpendicular to a principal plane of the substrate 111) as an example. The number of memory cell arrays may be two or more. Here, the memory cell arrays that are stacked adjacent to each other in the Z direction share lines. Meanwhile, the cross-point type memory cell array 102 may be formed of one memory cell array.

When the plurality of memory cell arrays M1, M2, M3, and M4 are stacked as illustrated in FIG. 6, the address signal includes, for example, a memory cell array selection signal, a row address signal, and a column address signal. The first and second control circuits 103 and 104 select one of the plurality of stacked memory cell arrays on the basis of, for example, the memory cell array selection signal. The first and second control circuits 103 and 104 can perform the writing, the erasing, and the reading of data on one of the plurality of stacked memory cell arrays, and can simultaneously perform the writing, the erasing, and the reading of data on two or more or all of the plurality of stacked memory cell arrays.

The memory cell array M1 is formed of a plurality of cell units CU1 that are disposed in the form of an array in the X direction and a Y direction. Similarly to the memory cell array M1, the memory cell array M2 is formed of a plurality of cell units CU2 disposed in the form of an array, the memory cell array M3 is formed of a plurality of cell units CU3 disposed in the form of an array, and the memory cell array M4 is formed of a plurality of cell units CU4 disposed in the form of an array. Each of the cell units CU1, CU2, CU3, and CU4 is formed of the variable resistive element that has been described in the first or second embodiment.

Further, lines L1(j−1), L1(j), and L1(j+1), lines L2(i−1), L2(i), and L2(i+1), lines L3(j−1), L3(j), and L3(j+1), lines L4(i−1), L4(i), and L4(i+1), and lines L5(j−1), L5(j), and L5(j+1) are disposed above the substrate 111 in this order from the substrate 111. Odd-numbered lines from the substrate 111, that is, the lines L1(j−1), L1(j), and L1(j+1), the lines L3(j−1), L3(j), and L3(j+1), and the lines L5(j−1), L5(j), and L5(j+1) extend in the Y direction. Furthermore, even-numbered lines from the semiconductor substrate 111, that is, the lines L2(i−1), L2(i), and L2(i+1) and the lines L4(i−1), L4(i), and L4(i+1) extend in the X direction. These lines are used as word lines or bit lines.

The first memory cell array M1, which is disposed at the lowest position, is disposed between the first lines L1(j−1), L1(j), and L1(j+1) and the second lines L2(i−1), L2(i), and L2(i+1). In the set/reset operation and the read operation performed on the memory cell array M1, one of the lines L1(j−1), L1(j), and L1(j+1) and the lines L2(i−1), L2(i), and L2(i+1) are used as word lines and the other thereof are used as bit lines.

The memory cell array M2 is disposed between the second lines L2(i−1), L2(i), and L2(i+1) and the third lines L3(j−1), L3(j), and L3(j+1). In the set/reset operation and the read operation performed on the memory cell array M2, one of the lines L2(i−1), L2(i), and L2(i+1) and the lines L3(j−1), L3(j), and L3(j+1) are used as word lines and the other thereof are used as bit lines.

The memory cell array M3 is disposed between the third lines L3(j−1), L3(j), and L3(j+1) and the fourth lines L4(i−1), L4(i), and L4(i+1). In the set/reset operation and the read operation performed on the memory cell array M3, one of the lines L3(j−1), L3(j), and L3(j+1) and the lines L4(i−1), L4(i), and L4(i+1) are used as word lines and the other thereof are used as bit lines.

The memory cell array M4 is disposed between the fourth lines L4(i−1), L4(i), and L4(i+1) and the fifth lines L5(j−1), L5(j), and L5(j+1). In the set/reset operation and the read operation performed on the memory cell array M4, one of the lines L4(i−1), L4(i), and L4(i+1) and the lines L5(j−1), L5(j), and L5(j+1) are used as word lines and the other thereof are used as bit lines.

Here, the cell units CU1, CU2, CU3, and CU4 are disposed at portions where the lines L1(j−1), L1(ⱼ), and L1(j+1) and the lines L2(i−1), L2(i), and L2(i+1) cross each other, portions where the lines L2(i−1), L2(i), and L2(i+1) and the lines L3(j−1), L3(j), and L3(j+1) cross each other, portions where the lines L3(j−1), L3(j), and L3(j+1) and the lines L4(i−1), L4(i), and L4(i+1) cross each other, and portions where the lines L4(i−1), L4(i), and L4(i+1) and the lines L5(j−1), L5(j), and L5(j+1) cross each other, respectively. That is, the cell units are disposed at the portions where the plurality of lines successively stacked in the Z direction cross each other in the cross-point type memory cell array 102.

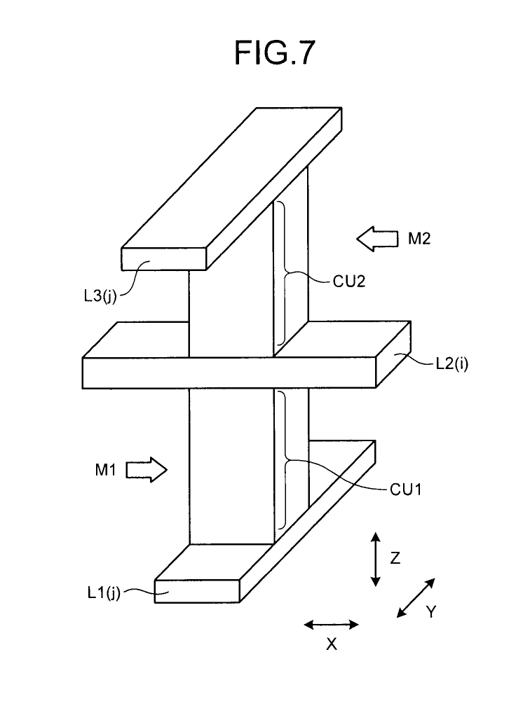

FIG. 7 is a perspective view illustrating an example of the structure of the lines and the cell units of the cross-point type memory cell array. The cell units CU1 and CU2 of the two memory cell arrays M1 and M2 of FIG. 6 are illustrated here. In this case, the structures of the cell units of the two memory cell arrays M3 and M4 of FIG. 6 are the same as the structures of the cell units of the two memory cell arrays M1 and M2 of FIG. 6.

Each of the cell units CU1 and CU2 is formed of a memory element. The memory element has a structure in which the variable resistive layer 13 and the tunnel barrier layer 12 are stacked between two electrodes as described in the first or second embodiment. However, in this case, the lines used as the bit lines or the word lines may serve as the first and second electrodes 11 and 14 of the first or second embodiment.

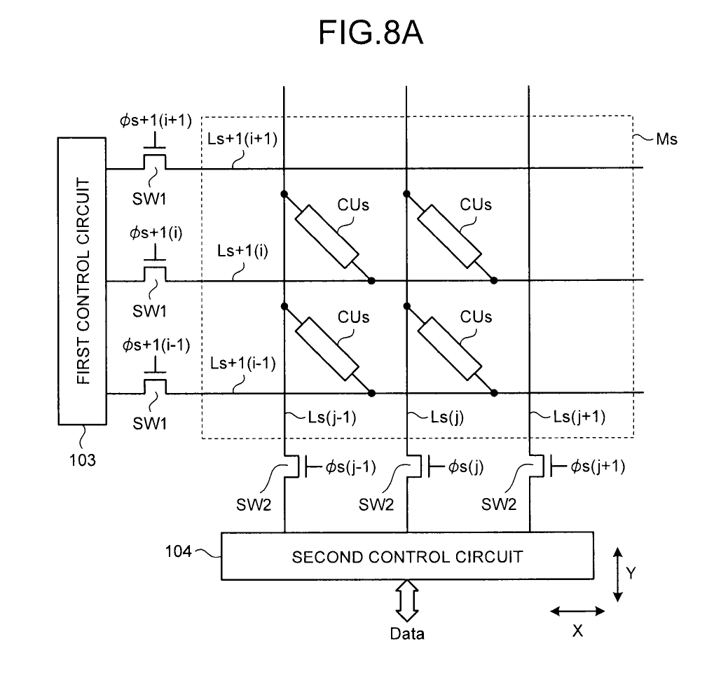

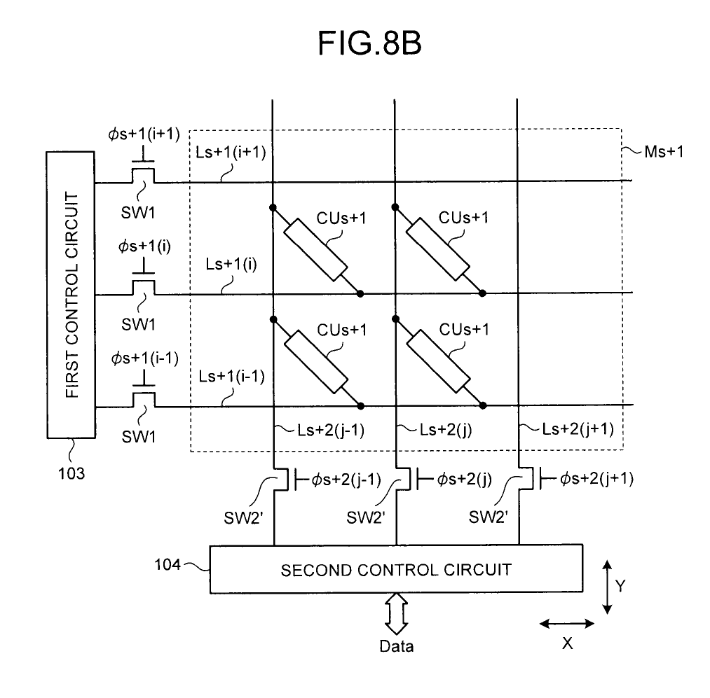

FIGS. 8A and 8B are diagrams illustrating a first example of a layout of the first and second control circuits. A memory cell array Ms, which corresponds to any one layer of the memory cell arrays M1, M2, M3, and M4 illustrated in FIG. 6, is formed of a plurality of cell units CUs that are disposed in the form of an array as illustrated in FIG. 8A. One ends of the cell units CUs are connected to lines Ls(j−1), Ls(j), and Ls(j+1), and the other ends of the cell units CUs are connected to lines Ls+1(i−1), Ls+1(i), and Ls+1(i+1).

A memory cell array Ms+1 is formed of a plurality of cell units CUs+1 that are disposed in the form of an array as illustrated in FIG. 8B. One ends of the cell units CUs+1 are connected to the lines Ls+1(i−1), Ls+1(i), and Ls+1(i+1), and the other ends of the cell units CUs+1 are connected to lines Ls+2(j−1), Ls+2(j), and Ls+2(j+1). However, s is 1, 3, 5, 7, . . . .

The first control circuit 103 is connected to one ends of the lines Ls+1(i−1), Ls+1(i), and Ls+1(i+1) in the X direction through switch elements SW1. The switch elements SW1 are controlled by, for example, control signals φs+1(i−1), φs+1(i), and Os+1(i+1). The switch element SW1 is formed of, for example, an N-channel field effect transistor (FET). The second control circuit 104 is connected to one ends of the lines Ls(j−1), Ls(j), and Ls(j+1) in the Y direction through switch elements SW2. The switch elements SW2 are controlled by, for example, control signals φs(j−1), φs(j), and φs(j+1). The switch element SW2 is formed of, for example, an N-channel FET. The second control circuit 104 is connected to one ends of the lines Ls+2(j−1), Ls+2(j), and Ls+2(j+1) in the Y direction through switch elements SW2′. The switch elements SW2′ are controlled by, for example, control signals φs+2(j−1), φs+2(j), and φ+2(j+1). The switch element SW2′ is formed of, for example, an N-channel FET.

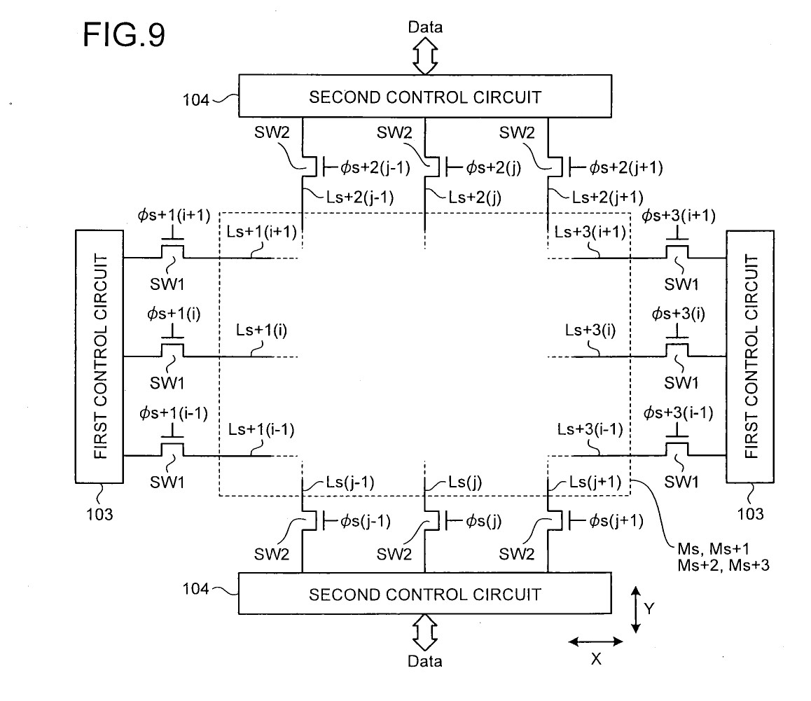

FIG. 9 is a diagram illustrating a second example of the layout of the first and second control circuits. Meanwhile, since the internal structures of memory cell arrays Ms, Ms+1, Ms+2, and Ms+3 of FIG. 9 are substantially the same as those of the memory cell arrays illustrated in FIG. 8A or 8B, the internal structures of the memory cell arrays are not illustrated in FIG. 9.

The layout of the second example is different from the layout of the first example in that first control circuits 103 are disposed at both ends of the memory cell arrays Ms, Ms+1, Ms+2, and Ms+3 in the X direction, respectively, and second control circuits 104 are disposed at both ends of the memory cell arrays Ms, Ms+1, Ms+2, and Ms+3 in the Y direction, respectively. However, s is 1, 5, 9, 13, . . . .

The first control circuits 103 are connected to both ends of the lines Ls+1(i−1), Ls+1(i), and Ls+1(i+1) in the X direction through switch elements SW1, respectively. The switch elements SW1 are controlled by, for example, control signals φs+1(i−1), φs+1(i), φs+1(i+1), φs+3(i−1), φs+3(i), and φs+3(i+1). The switch element SW1 is formed of, for example, an N-channel FET. The second control circuits 104 are connected to both ends of the lines Ls(j−1), Ls(j), and Ls(j+1) in the Y direction through switch elements SW2, respectively. The switch elements SW2 are controlled by, for example, control signals φs(j−1), φs(j), φs(j+1), φs+2(j−1), φs+2(j), and φ+2(j+1). The switch element SW2 is formed of, for example, an N-channel FET.

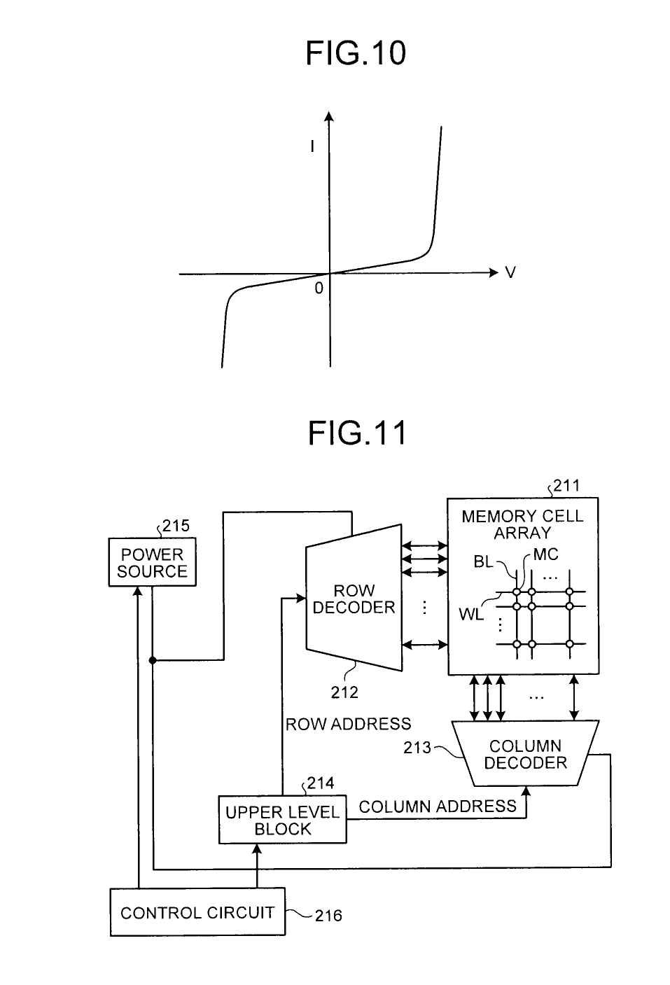

In the related art, a variable resistive layer and a diode were disposed in each of the cell units of the cross-point type memory cell array 102 so as to be connected to each other in series. However, in the first application example, a memory element having a structure in which the variable resistive layer 13 (which is formed of one layer in the case of the first embodiment and is formed of two layers having different resistances in the case of the second embodiment) and the tunnel barrier layer 12 described in the first or second embodiment are connected to each other in series has been disposed in the cell unit. FIG. 10 is a diagram schematically illustrating an example of voltage-current characteristics of the tunnel barrier layer. In FIG. 10, a horizontal axis represents a voltage applied to the tunnel barrier layer 12 and a vertical axis represents current flowing in the tunnel barrier layer 12. Since the tunnel barrier layer 12 has non-linearity as illustrated in FIG. 10, it is possible to obtain the same effect as an effect that is obtained when a diode is provided.

When set operation or reset operation is performed in a case in which a plurality of cell units not including diodes are connected to one line, there is a case in which the other cell units except for the selected cell unit may operate. However, since the tunnel barrier layer 12 has non-linear voltage-current characteristics illustrated in FIG. 10 in the case of the first application example, it is possible to prevent current from flowing in the other cell units except for the selected cell unit.

Further, since the thickness of the tunnel barrier layer 12 is sufficiently smaller than that of a diode that has been used in the related art, it is possible to make the size of the cell unit smaller than the past.

In the first application example, the variable resistive elements according to the first or second embodiment have been disposed at the positions where the first lines extending in the X direction and the second lines extending in the Y direction cross each other, and the switch elements have been connected to the variable resistive elements through the lines. As a result, since a variable resistive element and a selector (diode) have been provided at each of the positions where the first and second lines cross each other in the related art, it was not possible to reduce the size of the nonvolatile memory device. In contrast, in the first application example, it is possible to achieve the same function as the function of a diode while excluding diodes from the structure. Accordingly, it is possible to obtain an effect of reducing the size of the nonvolatile memory device by the thickness of the diode, in addition to the effects of the first and second embodiments.

### Second Application Example

The memory cells of the first and second embodiments can be applied to a nonvolatile memory device using the following variable resistive elements. A case in which the memory cells of the first and second embodiments are applied to a nonvolatile memory device having nR-1Tr structure in which n (n is a natural number equal to or larger than 2) variable resistive elements are connected to one selection transistor will be described in a second application example.

FIG. 11 is a diagram illustrating an example of a main part of a nonvolatile memory device according to a second application example. The nonvolatile memory device includes a memory cell array 211, a row decoder 212, a column decoder 213, an upper level block 214, a power source 215, and a control circuit 216.

The memory cell array 211 includes a plurality of word lines WL and a plurality of bit lines BL that cross each other and memory cells MC that are disposed at portions where the word lines WL and the bit lines BL cross each other. The row decoder 212 selects a word line WL during access (the erasing, the writing, and the reading of data). The column decoder 213 selects a bit line BL during access, and includes a driver that controls an access operation.

The upper level block 214 selects a memory cell MC that is an access object in the memory cell array 211. The upper level block 214 gives a row address and a column address to the row decoder 212 and the column decoder 213. The power source 215 generates a combination of predetermined voltages corresponding to an operation for erasing data, an operation for writing data, and an operation for reading data, and supplies the combination to the row decoder 212 and the column decoder 213. The control circuit 216 performs control to send an address to the upper level block 214, or the like according to a command from the outside, and also controls the power source 215.

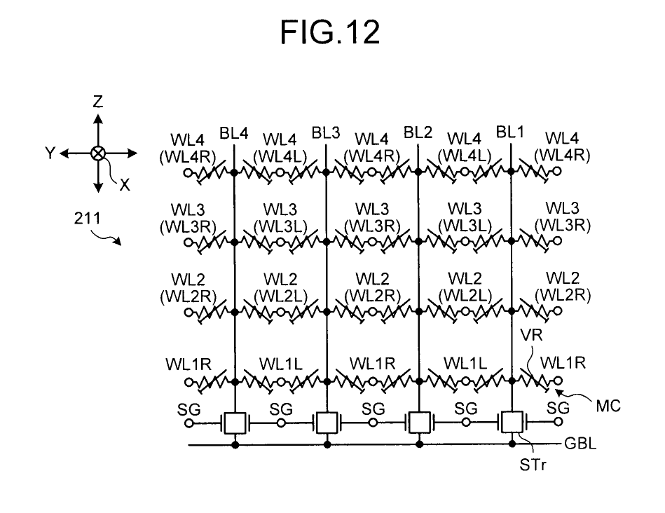

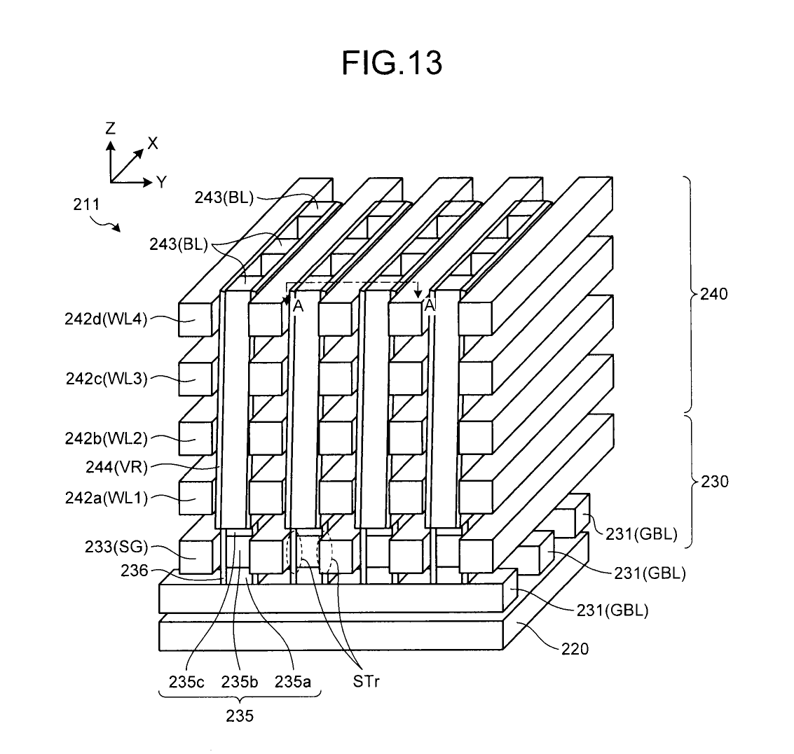

FIG. 12 is a diagram illustrating an example of a circuit diagram of the memory cell array, and FIG. 13 is a perspective view illustrating an example of the stacked structure of the memory cell array. Meanwhile, an X direction, a Y direction, and a Z direction are perpendicular to each other in FIG. 12, and the X direction is a direction perpendicular to the plane of FIG. 12. Further, the structure illustrated in FIG. 12 is repeatedly provided in the X direction.

As illustrated in FIG. 12, the memory cell array 211 includes selection transistors STr, global bit lines GBL, and selection gate lines SG, in addition to the word lines WL, the bit lines BL, and the memory cells MC that have been described above.

As illustrated in FIGS. 12 and 13, the word lines WL1 to WL4 are arranged at a predetermined pitch in the Z direction and extend in the X direction. The bit lines BL are arranged in the form of a matrix in the X direction and the Y direction, and extend in the Z direction. The memory cells MC are disposed at portions where the word lines WL and the bit lines BL cross each other. Accordingly, the memory cells MC are arranged in the form of a three-dimensional matrix in the X direction, the Y direction, and the Z direction. As illustrated in FIG. 12, the memory cells MC include variable resistive elements VR. The variable resistive element, which has been described in the first or second embodiment, is used as the variable resistive element VR.

As illustrated in FIG. 12, the selection transistors STr are provided between one ends of the bit lines BL and the global bit lines GBL. The global bit lines GBL are arranged side by side at a predetermined pitch in the X direction, and extend in the Y direction. One global bit line GBL is connected in common to one ends of the plurality of selection transistors STr that are arranged in line in the Y direction.

Further, gate electrodes of two selection transistors STr, which are arranged adjacent to each other in the Y direction, can be connected in common to each other. The selection gate lines SG are arranged side by side at a predetermined pitch in the Y direction, and extend in the X direction. One selection gate line SG is connected in common to the gate electrodes of the plurality of selection transistors STr that are arranged in line in the X direction. Meanwhile, it is also possible to independently operate two selection transistors STr by separating the gate electrodes of the two selection transistors STr, which are arranged adjacent to each other in the Y direction, from each other.

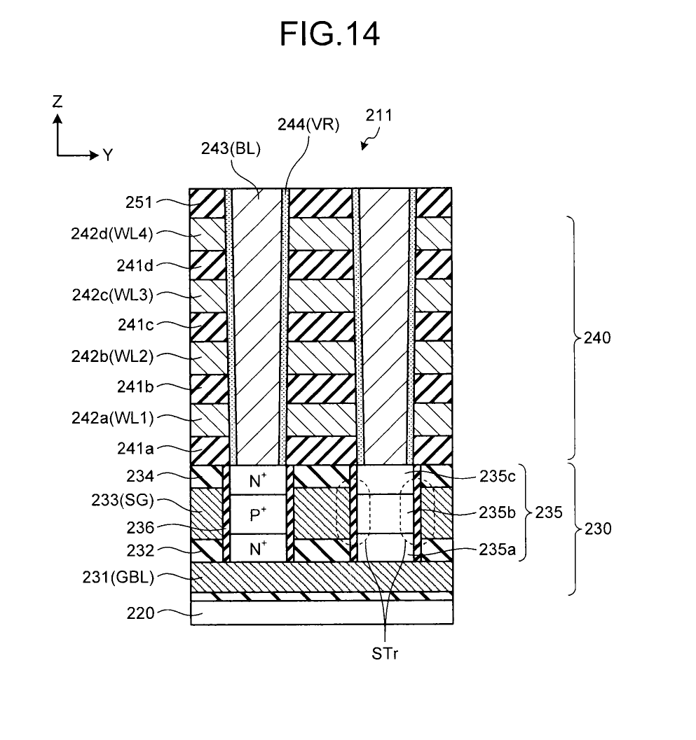

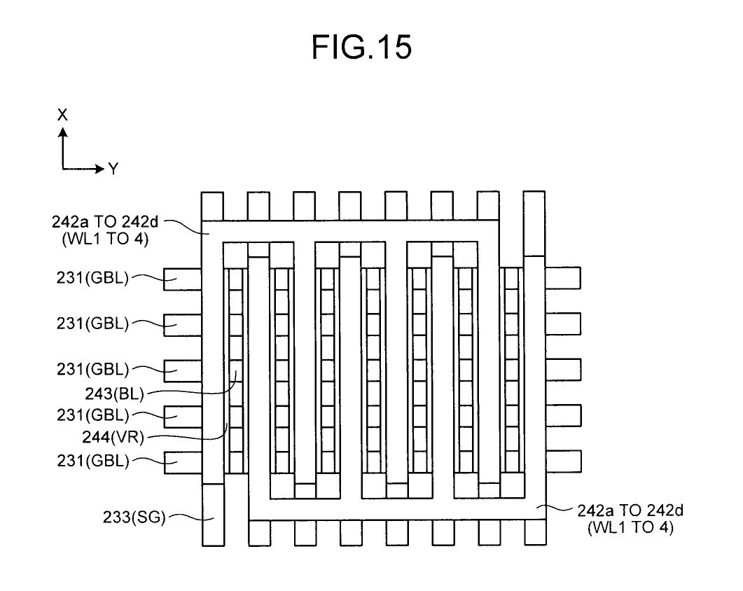

Next, the stacked structure of the memory cell array 211 of the second application example will be described. FIG. 14 is an example of a cross-sectional view taken along line A-A of FIG. 13, and FIG. 15 is an example of a top view of FIG. 13. Meanwhile, an interlayer insulating film is not illustrated in FIGS. 13 and 15.

As illustrated in FIGS. 13 and 14, the memory cell array 211 includes a selection transistor layer 230 and a memory layer 240 that are stacked above a substrate 220. The selection transistor layer 230 functions as the selection transistor STr, and the memory layer 240 functions as the memory cell MC.

As illustrated in FIGS. 13 and 14, the selection transistor layer 230 includes conductive layers 231, interlayer insulating films 232, conductive layers 233, and interlayer insulating films 234. The conductive layers 231, the interlayer insulating films 232, the conductive layers 233, and the interlayer insulating films 234 are stacked in the Z direction that is perpendicular to the substrate 220. The conductive layers 231 function as the global bit lines GBL, and the conductive layers 233 function as the selection gate lines SG and the gates of the selection transistors STr.

The conductive layers 231 have the shape of stripes that are arranged side by side at a predetermined pitch in the X direction parallel to the substrate 220 and extend in the Y direction (see FIG. 15). Although not illustrated in FIG. 13, interlayer insulating films are formed between the plurality of conductive layers 231.

The interlayer insulating films 232 are formed so as to cover the upper surfaces of the conductive layers 231, and function to electrically insulate the conductive layers 231 from the selection gate lines SG (conductive layers 233). The conductive layers 233 are formed in the shape of stripes that are arranged side by side at a predetermined pitch in the Y direction and extend in the X direction (see FIG. 15). The interlayer insulating films 234 are deposited so as to cover side surfaces and upper surfaces of the conductive layers 233. For example, the conductive layers 231 and 233 are made of polysilicon. The interlayer insulating films 232 and 234 are made of a silicon oxide (SiO₂).

Further, the selection transistor layer 230 includes, for example, pillar-shaped semiconductor layers 235 and gate insulating layers 236 as illustrated in FIGS. 13 and 14. The semiconductor layers 235 function as bodies (channels) of the selection transistors STr, and the gate insulating layers 236 function as gate insulating films of the selection transistors STr.

The semiconductor layers 235 are disposed in the shape of a matrix in the X direction and the Y direction, and extend in the Z direction. Furthermore, the semiconductor layers 235 come into contact with the upper surfaces of the conductive layers 231, and come into contact with the side surfaces of the conductive layers 233 in the Y direction through the gate insulating layers 236. Moreover, the semiconductor layer 235 includes an N+type semiconductor layer 235a, a P+ type semiconductor layer 235b, and an N+ type semiconductor layer 235c that are stacked from the lower side toward the upper side in the Z direction.

As illustrated in FIGS. 13 and 14, side surfaces of the N+ type semiconductor layers 235a in the Y direction come into contact with the interlayer insulating films 232 through the gate insulating layers 236. Side surfaces of the P+ type semiconductor layers 235b in the Y direction come into contact with the side surfaces of the conductive layers 233 through the gate insulating layers 236. Side surfaces of the N+ type semiconductor layers 235c in the Y direction come into contact with the interlayer insulating films 234 through the gate insulating layers 236. The N+ type semiconductor layers 235a and 235c are made of polysilicon into which an N+ type dopant is implanted, and the P+ type semiconductor layer 235b is made of polysilicon into which a P+ type dopant is implanted. The gate insulating layer 236 is made of, for example, a silicon oxide (SiO₂). Meanwhile, a barrier metal layer may be formed between the semiconductor layer 235 and a conductive layer 243 to be described below and between the semiconductor layer and the conductive layer 231 (the barrier metal layer is not illustrated in FIG. 14).

As illustrated in FIGS. 13 and 14, the memory layer 240 includes interlayer insulating films 241a to 241d and 251 and conductive layers 242a to 242d that are alternately stacked in the Z direction. The conductive layers 242a to 242d function as the word lines WL1 to WL4, respectively. Each of the conductive layers 242a to 242d has the shape of a pair of comb teeth, which face each other in the X direction, when viewed in the Z direction (see FIG. 15). That is, word lines WLiR (i=1 to 4), which belong to one of the conductive layers having the shape of a pair of comb teeth, and word lines WLiL, which belong to the other thereof, are alternately formed in the Y direction (see FIG. 12). It is possible to reduce the number of contacts, which are connected to the word lines WL, by employing the conductive layers that have the shape of comb teeth. Meanwhile, the interlayer insulating films 241a to 241d and 251 are made of, for example, a silicon oxide (SiO₂), and the conductive layers 242a to 242d are made of, for example, polysilicon.

Further, as illustrated in FIGS. 13 and 14, the memory layer 240 includes, for example, pillar-shaped conductive layers 243 and variable resistive element forming layers 244. The variable resistive element forming layers 244 are provided so as to be shared on both side surfaces of the plurality of pillar-shaped conductive layers 243, which are arranged in the X direction, in the Y direction. The conductive layers 243 function as the bit lines BL. The variable resistive element forming layers 244 function as the variable resistive elements VR, which have been described in the first or second embodiment, in the area that is interposed between the conductive layers 243 and the conductive layers 242a to 242d. However, in this case, the conductive layers 243 and 244, which function as the bit lines or the word lines, may be adopted so as to function as the first and second electrodes 11 and 14 of the first or second embodiment.

The conductive layers 243 are disposed in the form of a matrix in the X direction and the Y direction. The lower ends of the conductive layers 243 come into contact with the upper surfaces of the semiconductor layers 235, and the conductive layers 243 extend in the form of a post in the Z direction. Although not illustrated in FIG. 13, interlayer insulating films are formed between the conductive layers 243 that are arranged side by side in the X direction.

The variable resistive element forming layers 244 are provided between the side surfaces of the conductive layer 243 in the Y direction and the side surfaces of the interlayer insulating films 241a to 241d in the Y direction. Further, the variable resistive element forming layers 244 are provided between the side surfaces of the conductive layers 243 in the Y direction and the side surfaces of the conductive layers 242a to 242d in the Y direction. The conductive layers 243 are made of, for example, polysilicon. Furthermore, the variable resistive element forming layer 244 has a structure in which the variable resistive layer 13 and the tunnel barrier layer 12 are stacked.

Next, a set operation, a reset operation, and a read operation for the nonvolatile memory device having this structure will be described briefly.

When a set operation for changing a certain selected memory cell MC to a low-resistance state from a high-resistance state is performed, a predetermined set voltage Vset is applied to a selected global bit line GBL corresponding to a bit line BL to which the memory cell MC is connected and a voltage of, for example, 0 V is applied to the other unselect global bit lines GBL. Further, a voltage of, for example, 0 V is applied to a selected word line WL to which the selected memory cell MC is connected, and a voltage Vset/2, which is a half of the set voltage Vset, is applied to the other unselect word lines. Furthermore, current is selectively applied to a selection transistor STr to which the bit line BL is connected, and the other selection transistors are maintained in a non-conductive state. Accordingly, the set voltage Vset is applied to only the selected memory cell MC, so that the set operation is performed.

Moreover, when a reset operation for changing a certain selected memory cell MC to a high-resistance state from a low-resistance state is performed, a predetermined reset voltage Vreset is applied to a selected global bit line GBL corresponding to a bit line BL to which the memory cell MC is connected and a voltage of, for example, 0 V is applied to the other unselect global bit lines GBL. Further, a voltage of, for example, 0 V is applied to a selected word line WL to which the selected memory cell MC is connected, and a voltage Vreset/2, which is a half of the reset voltage Vreset, is applied to the other unselect word lines. Furthermore, current is selectively applied to a selection transistor STr to which the bit line BL is connected, and the other selection transistors are maintained in a non-conductive state. Accordingly, the reset voltage Vreset is applied to only the selected memory cell MC, so that the set operation is performed.

In a read operation for reading the state of a memory cell, a predetermined read voltage Vread is applied to a selected global bit line GBL corresponding to a bit line BL to which the memory cell MC is connected and a voltage of, for example, 0 V is applied to the other unselect global bit lines GBL. Further, a voltage of, for example, 0 V is applied to a selected word line WL to which the selected memory cell MC is connected, and a voltage Vread/2, which is a half of the read voltage Vread, is applied to the other unselect word lines. Furthermore, current is selectively applied to a selection transistor STr to which the bit line BL is connected, and the other selection transistors are maintained in a non-conductive state. Accordingly, the read voltage Vread is applied to only the selected memory cell MC, so that the read operation is performed.

Even in the nonvolatile memory device of the second application example, as described in the first application example, a memory element having a structure in which the variable resistive layer 13 (which is formed of one layer in the case of the first embodiment and is formed of two layers having different resistances in the case of the second embodiment) and the tunnel barrier layer 12 described in the first or second embodiment are connected to each other in series has been disposed without disposing a diode in the memory cell. Since the tunnel barrier layer 12 has non-linearity as illustrated in FIG. 10, it is possible to obtain the same effect as an effect, which is obtained when a diode is provided, by providing the tunnel barrier layer 12 in the memory cell. For this reason, it is possible to prevent current from flowing in the other memory cells except for the selected memory cell when data are deleted, written, and read.

Further, in the nonvolatile memory device having a three-dimensional structure as illustrated in FIG. 13, it is possible to reduce the size of each memory cell by providing the tunnel barrier layer 12 without providing a diode.

In the second application example, the variable resistive element described in the first or second embodiment has been disposed at each of the positions where the bit lines two-dimensionally disposed and extending in the Z direction and the word lines extending in the X direction cross each other. Even though the nonvolatile memory device in which the variable resistive elements are three-dimensionally disposed as described above has a limit in the thickness direction, the nonvolatile memory device has an effect of obtaining a load resistor effect by the tunnel barrier layer 12, which is disposed in the variable resistive element, without the increase of the thickness of the variable resistive layer 13.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory device comprising:
a first wiring that extends in a first direction;
a second wiring that is formed at a height different from the height of the first wiring and extends in a second direction crossing the first direction; and
a memory cell that is disposed at a position where the first and second wirings cross so as to be interposed between the first and second wirings,
wherein the memory cell includes a variable resistive layer of which a resistance state is able to be changed by an electrical signal to be applied, and a tunnel barrier layer that is formed of an insulating film provided in contact with the variable resistive layer, and
the tunnel barrier layer is provided close to the first wiring to which a positive voltage with applied during set operation changing the variable resistive layer to a low-resistance state from a high-resistance state.

2. The nonvolatile memory device according to claim 1,
wherein the thickness of the tunnel barrier layer is equal to or smaller than the thickness of the variable resistive layer.

3. The nonvolatile memory device according to claim 1,
wherein the tunnel barrier layer is made of a metal oxide or a metal nitride.

4. The nonvolatile memory device according to claim 3,
wherein the tunnel barrier layer is made of at least one selected from a group consisting of a silicon oxide, a silicon nitride, an aluminum oxide, an aluminum nitride, Ta₂O₅, HfO₂, and ZrO₂.

5. The nonvolatile memory device according to claim 1,
wherein the variable resistive layer is made of a material of which a resistance value is reversibly changed on the basis of electrical signals that are given between the first and second wirings and have different polarities.

6. The nonvolatile memory device according to claim 1,
wherein the variable resistive layer includes a first layer that is formed in contact with the tunnel barrier layer, and a second layer which is formed in contact with the first layer and of which the resistivity is higher than the resistivity of the first layer.

7. The nonvolatile memory device according to claim 6,
wherein the thickness of the second layer is different from the thickness of the tunnel barrier layer.

8. The nonvolatile memory device according to claim 7,
wherein the thickness of the tunnel barrier layer is equal to or smaller than the thickness of the second layer.

9. The nonvolatile memory device according to claim 7,
wherein the thickness of the tunnel barrier layer is larger than the thickness of the second layer.

10. The nonvolatile memory device according to claim 6,
wherein a band gap of the tunnel barrier layer is equal to or smaller than a band gap of the second layer.

11. The nonvolatile memory device according to claim 6,
wherein a band gap of the tunnel barrier layer is equal to or larger than a band gap of the first layer.

12. A nonvolatile memory device comprising:
a plurality of first wirings that are disposed in a first direction and a second direction crossing and extend in a third direction perpendicular to the first and second directions;
a plurality of second wirings that extend in the second direction and are provided at an interval in the third direction of the first wirings;
memory cells that are disposed at positions where the first and second wirings cross so as to be interposed between the first and second wirings; and
selection transistors that are provided at end portions of the first wirings,
wherein the memory cell includes a variable resistive layer of which a resistance state is able to be changed by an electrical signal to be applied, and a tunnel barrier layer that is formed of an insulating film provided in contact with the variable resistive layer, and
the tunnel barrier layer is provided close to a wiring to which a positive voltage with the first wiring is applied during set operation changing the variable resistive layer to a low-resistance state from a high-resistance state.

13. The nonvolatile memory device according to claim 12,
wherein the thickness of the tunnel barrier layer is equal to or smaller than the thickness of the variable resistive layer.

14. The nonvolatile memory device according to claim 12,
wherein the tunnel barrier layer is made of a metal oxide or a metal nitride.

15. The nonvolatile memory device according to claim 14,
wherein the tunnel barrier layer is made of at least one selected from a group consisting of a silicon oxide, a silicon nitride, an aluminum oxide, an aluminum nitride, Ta₂O₅, HfO₂, and ZrO₂.

16. The nonvolatile memory device according to claim 12,
wherein the variable resistive layer is made of a material of which a resistance value is reversibly changed on the basis of electrical signals that are given between the first and second wirings and have different polarities.

17. The nonvolatile memory device according to claim 12,
wherein the variable resistive layer includes a first layer that is formed in contact with the tunnel barrier layer, and a second layer which is formed in contact with the first layer and of which the resistivity is higher than the resistivity of the first layer.

18. The nonvolatile memory device according to claim 17,
wherein the thickness of the second layer is different from the thickness of the tunnel barrier layer.

19. The nonvolatile memory device according to claim 18,
wherein the thickness of the tunnel barrier layer is equal to or smaller than the thickness of the second layer.
